(19) United States
(12) Patent Application Publication
(10) Pub. No.: US 2018/0337454 A1
(43) Pub. Date: Nov. 22, 2018

(54) FILTER MODULE AND FRONT END MODULE INCLUDING THE SAME

(71) Applicant: Samsung Electro-Mechanics Co., Ltd., Suwon-si (KR)

(72) Inventors: Myeong Woo HAN, Suwon-si (KR); Chan Yong JEONG, Suwon-si (KR)

(73) Assignee: Samsung Electro-Mechanics Co., Ltd., Suwon-si (KR)

(21) Appl. No.: 15/790,904

(22) Filed: Oct. 23, 2017

(30) Foreign Application Priority Data
May 16, 2017 (KR) 10-2017-0060621

(51) Int. Cl. H01Q 5/50; H03H 9/56; H03H 9/70; H01Q 1/24

(52) U.S. Cl. CPC H01Q 5/50; H01Q 1/243; H03H 9/706; H03H 9/564

(57) ABSTRACT

A filter module includes: a first substrate and a second substrate coupled to each other to form an internal space; a first filter formed on the first substrate, in the internal space, and including a bulk acoustic resonator; and a second filter disposed on the second substrate, wherein the first and second filters are configured to filter frequencies within different bands.

### CROSS-REFERENCE TO RELATED APPLICATIONS

This application claims the benefit under 35 U.S.C. § 119(a) of Korean Patent Application No. 10-2017-0060621 filed on May 16, 2017 in the Korean Intellectual Property Office, the entire disclosure of which is incorporated herein by reference for all purposes.

### BACKGROUND

### 1. Field

The following description relates to a filter module and a front end module including the filter module.

### 2. Description of Related Art

Recently developed electronic devices, or terminals, support a communications service using different communications networks, for example, a global system for mobile communications (GSM) network and a long term evolution (LTE) network.

Such a terminal for GSM and LTE includes a front end module connected to an antenna terminal. Generally, the front end module includes a switch element connected to an antenna, a duplexer or a filter element configured to isolate bands of radio frequency signals transmitted and received through the antenna or to pass specific bands of the radio frequency signals therethrough, and an amplifying element configured to amplify the transmitted radio frequency signals.

In general, the front end module has used separate filters for each band of the radio frequency signals. However, in such a case, the use of the separate filters limits the ability to reduce a size of the front end module, and it is thus difficult to minimize the size of an electronic device in which the front end module is mounted.

### SUMMARY

In one general aspect, a filter module includes: a first substrate and a second substrate coupled to each other to form an internal space; a first filter formed on the first substrate, in the internal space, and including a bulk acoustic resonator; and a second filter disposed on the second substrate, wherein the first and second filters are configured to filter frequencies within different bands.

The second filter may include either one of an active filter and a passive filter.

The second filter may include any one of a diplexer (DPX), a low pass filter (LPF), a high pass filter (HPF), a band pass filter (BPF), and a coupler.

The second filter may be disposed in the internal space.

The second filter may be formed on an external surface of the second substrate.

The first and second substrates may include high resistivity silicon (HRS) substrates.

The first filter may be configured to filter frequencies within a first band, among the frequencies within the different bands. The second filter may be configured to filter frequencies within a second band, among the frequencies within the different bands.

The frequencies within the first band may include frequencies within a 2 GHz band. The frequencies within the second band may include frequencies within a 5 GHz band.

In another general aspect, a front end module may include: an antenna configured to transmit and receive radio frequency signals in frequency bands; a diplexer configured to isolate the radio frequency signals received through the antenna in each of the frequency bands; and a filter module configured independently receive and filter the isolated radio frequency signals from the diplexer, wherein the filter module includes a first filter including a bulk acoustic resonator, and a second filter including either one of a passive filter and an active filter.

The filter module may further include a first substrate and a second substrate coupled to each other to form an internal space. The bulk acoustic resonator may be disposed on the first substrate, in the internal space. The either one of the passive filter and the active filter may be disposed on the second substrate.

The either one of the passive filter and the active filter may be disposed in the internal space, facing the bulk acoustic resonator.

The either one of the passive filter and the active filter may be disposed on an external surface of the second substrate.

The first filter may be configured to receive and filter first radio frequency signals, among the isolated radio frequency signals, that are in a first frequency band, among the frequency bands. The second filter may be configured to receive and filter second radio frequency signals, among the isolated radio frequency signals, that are in a second frequency band, among the frequency bands.

The first frequency band may include a 2 GHz frequency band, and the second frequency band may include a 5 GHz frequency band.

Other features and aspects will be apparent from the following detailed description, the drawings, and the claims.

### BRIEF DESCRIPTION OF DRAWINGS

FIG. 1 is a schematic cross-sectional view illustrating a filter module, according to an embodiment.

FIG. 2 is a schematic perspective view illustrating a second filter of the filter module of FIG. 1.

FIG. 3 is a cross-sectional view illustrating a filter module, according to another embodiment.

FIG. 4 is a perspective view illustrating the filter module of FIG. 3.

FIG. 5 is a cross-sectional view illustrating a filter module, according to another embodiment.

FIG. 6 is a block diagram illustrating an example of a front end module including a filter module, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” “coupled to,” “over,” or “covering” another element, it may be directly “on,” “connected to,” “coupled to,” “over,” or “covering” the other element, or there may be one or more other elements intervening therebetween. In contrast, when an element is described as being “directly on,” “directly connected to,” “directly coupled to,” “directly over,” or “directly covering” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, embodiments will be described in detail with reference to the accompanying drawings.

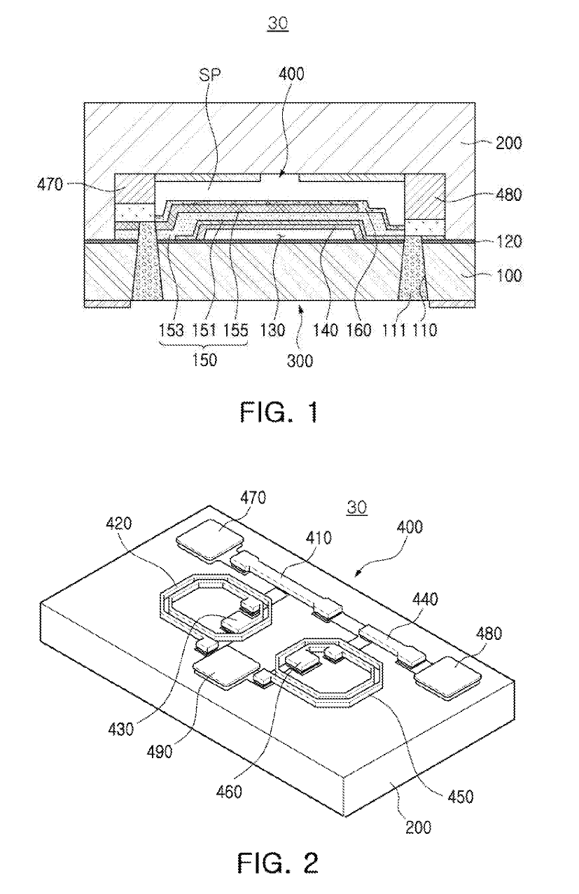

FIG. 1 is a schematic cross-sectional view illustrating a filter module 30, according to an embodiment. FIG. 2 is a schematic perspective view illustrating a second filter 400 of the filter module 30.

Referring to FIG. 1, the filter module 30 includes a filters configured to filter frequencies within different bands. As an example, the filter module, or filter device, 30 includes a first substrate 100, a second substrate 200, a first filter 300 disposed on the first substrate 100, and a second filter 400 disposed on the second substrate 200.

The first substrate 100 and the second substrate 200 are coupled to each other to form an internal space SP. The first substrate 100 and the second substrate 200 may be high resistivity silicon (HRS) substrates. Therefore, the first substrate 100 and the second substrate 200 have excellent signal isolation characteristics to implement a high quality (Q) factor value and a low loss signal line.

The first filter 300 is formed on the first substrate 100 and is disposed in the internal space SP formed by the first substrate 100 and the second substrate 200.

A bulk acoustic resonator may include one or more filters. As an example, a bulk acoustic resonator includes the first filter 300, or the first filter 300 includes a bulk acoustic resonator. The bulk acoustic resonator may be a film bulk acoustic resonator (FBAR).

The bulk acoustic resonator is implemented by a multilayer structure including a plurality of films. For example, the bulk acoustic resonator includes an insulating layer 120, an air cavity 130, and a resonant part 150.

The insulating layer 120 electrically isolates the resonant part 150 from the first substrate 100, and is disposed on an upper surface of the first substrate 100. The insulating layer 120 may be formed on the first substrate 100 by performing chemical vapor deposition, radio frequency (RF) magnetron sputtering, or evaporation using a silicon dioxide (SiO₂) or an aluminum oxide (Al₂O₃).

The air cavity 130 is disposed on the insulating layer 120. The air cavity 130 is positioned below the resonant part 150 so that the resonant part 150 can vibrate in a predetermined direction. The air cavity 130 may be formed by a process of forming an air cavity sacrificial layer pattern on the insulating layer 120, forming a membrane 140 on the air cavity sacrificial layer pattern, and then etching and removing the air cavity sacrificial layer pattern. The membrane 140 may be an oxidation protecting film, or may be a protecting layer protecting the first substrate 100.

An etch stop layer may be additionally formed between the insulating layer 120 and the air cavity 130. The etch stop layer protects the first substrate 100 and the insulating layer 120 from an etching process, and is a base for depositing other layers on the etch stop layer.

The resonant part 150 includes a first electrode 151, a piezoelectric layer 153, and a second electrode 155 sequentially stacked on the membrane 140. A common region in which the first electrode 151, the piezoelectric layer 153, and the second electrode 155 overlap one another in a vertical direction is positioned above the air cavity 130.

The first electrode 151 and the second electrode 155 may be formed of any one of gold (Au), titanium (Ti), tantalum (Ta), molybdenum (Mo), ruthenium (Ru), platinum (Pt), tungsten (W), aluminum (Al), iridium (Ir), and nickel (Ni), or alloys thereof.

The piezoelectric layer 153, which generates a piezoelectric effect in which electric energy is converted into mechanical energy having an elastic wave form, may be formed of any one of an aluminum nitride (AlN), a zinc oxide (ZnO), and a lead zirconate titanate oxide (PZT; PbZrTiO). In addition, the piezoelectric layer 153 may further include a rare earth metal. As an example, the rare earth metal includes any one or any combination of any two or more of scandium (Sc), erbium (Er), yttrium (Y), and lanthanum (La). The piezoelectric layer 153 may include 1 to 20 at % of rare earth metal.

A seed layer for improving crystal alignment of the piezoelectric layer 153 may be additionally disposed below the first electrode 151. The seed layer may be formed of any one of an aluminum nitride (AlN), a zinc oxide (ZnO), and a lead zirconate titanate oxide (PZT; PbZrTiO) having the same crystallinity as that of the piezoelectric layer 153.

The resonant part 150 includes an active region and an inactive region. The active region of the resonant part 150, which is a region that vibrates and resonates in a predetermined direction due to a piezoelectric phenomenon generated in the piezoelectric layer 153 when electric energy, such as a radio frequency signal, is applied to the first electrode 151 and the second electrode 155, is a region in which the first electrode 151, the piezoelectric layer 153, and the second electrode 155 overlap one another in the vertical direction above the air cavity 130. The inactive region of the resonant part 150, which is a region that does not resonate due to the piezoelectric phenomenon even when the electric energy is applied to the first and second electrodes 151 and 153, is a region outside the active region.

The resonant part 150 outputs a radio frequency signal having a specific frequency using the piezoelectric phenomenon. In detail, the resonant part 150 outputs a radio frequency signal having a resonant frequency corresponding to vibrations depending on the piezoelectric phenomenon of the piezoelectric layer 153.

A protecting layer 160 is disposed on the second electrode 155 of the resonant part 150 to prevent the second electrode 155 from being externally exposed. The protecting layer 160 may be formed of any one of a silicon oxide based insulating material, a silicon nitride based insulating material, and an aluminum nitride based insulating material.

At least one via hole 110 penetrating through the first substrate 100 in a thickness direction is formed in a lower surface of the first substrate 100. The via hole 110 penetrates through portions of the insulating layer 120, the first electrode 151, the piezoelectric layer 153, and the second electrode 155 in the thickness direction, in addition to the first substrate 100. A connection pattern 111 is formed in the via hole 110, and may be formed over the entirety of an inner surface, that is, an inner wall, of the via hole 110.

The connection pattern 111 may be manufactured by forming a conductive layer on the inner surface of the via hole 110. For example, the connection pattern 111 is formed by depositing, applying, or filling at one or more conductive metals such as gold (Au), copper (Cu), and a titanium (Ti)-copper (Cu) alloy along the inner wall of the via hole 110.

The connection pattern 111 is connected to either one or both of the first electrode 151 and the second electrode 155. As an example, the connection pattern 111 penetrates through at least portions of the first substrate 100, the insulating layer 120, the first electrode 151, and the piezoelectric layer 153, and the second electrode 155, and is then electrically connected to either one or both of the first electrode 151 and the second electrode 155. The connection pattern 111 extends to the lower surface of the first substrate 100 to be thus connected to a substrate connection pad provided on the lower surface of the first substrate 100. Therefore, the connection pattern 111 electrically connects the first electrode 151 and the second electrode 155 to the substrate connection pad.

The substrate connection pad is electrically connected to an external substrate that is disposed below the first filter 300 through a bump. The first filter 300 performs a filtering operation of a radio frequency signal by a signal applied to the first and second electrodes 151 and 155 through the substrate connection pad.

The second substrate 200 is bonded to the multilayer structure forming the first filter 300 to protect the first filter 300 from an external environment. The second substrate 200 has a cover form with the internal space SP in which the first filter 300 is disposed. The second substrate 200 has a hexahedral shape in which a lower surface of the hexahedral shape is opened, and thus has an upper surface and side surfaces.

For example, the second substrate 200 includes an accommodating part formed at the center of the second substrate 200 to accommodate the resonant part 150 of the first filter 300 therein, and an outer region of the accommodating part is bonded to a bonded region of the multilayer structure. The bonded region of the multilayer structure corresponds to an edge of the multilayer structure.

Although FIG. 1 illustrates a case in which the second substrate 200 is bonded to the insulating layer 120, which is stacked on the first substrate 100, the second substrate 200 may also be bonded to any one or any combination of any two or more of the membrane 140, the etch stop layer, and the first substrate 100, in addition to the insulating layer 120.

The filter module 30 includes the filters configured to filter frequencies within different bands. For example, the filter module 30 includes the second filter 400 formed on the second substrate 200, in addition to the first filter 300 formed on the first substrate 100.

As illustrated in FIG. 2, the second filter 400 may be a band pass filter (BPF). However, the second filter 400 is not limited to the band pass filter (BPF), and may be an active filter such as a diplexer (DPX), a low pass filter (LPF), a high pass filter (HPF), or a coupler, or may be a passive filter.

Referring to FIG. 2, the second filter 400 includes spiral inductors 420 and 450, capacitors 430 and 460, input and output ports 470 and 480, a ground 490, and circuit lines 410 and 440 formed on the second substrate 200. The circuit lines 410 and 440 connect the input and output ports 470 and 480 to the spiral inductors 420 and 450 and the capacitors 430 and 460, respectively.

The second filter 400 is formed on the substrate 200 and is disposed in the internal space SP. In addition, the first filter 300 and the second filter 400 are disposed to face each other in the internal space SP.

Therefore, the first filter 300 and the second filter 400 are disposed in the internal space SP formed by the first substrate 100 and the second substrate 200. That is, the filters 300 and 400 are disposed in the filter module 30, and the filter module 30 may thus be miniaturized, resulting in miniaturization of an electronic device in which the filter module 30 is mounted.

The second filter 400 may be electrically connected to the connection pattern 111 formed in the via hole 110 of the first substrate 100 to be thus electrically connected to the external substrate. Therefore, the second filter 400 may perform a filter operation of a radio frequency signal.

In the present exemplary embodiment, the first filter 300 and the second filter 400 may filter frequencies within different bands.

As an example, the first filter 300 may filter a frequency in a 2 gigahertz (GHz) band, and the second filter 400 may filter a frequency in a 5 GHz band.

That is, the plurality of filters that may filter the frequencies in the different bands may be implemented in a filter module, resulting in the miniaturization of the electronic device.

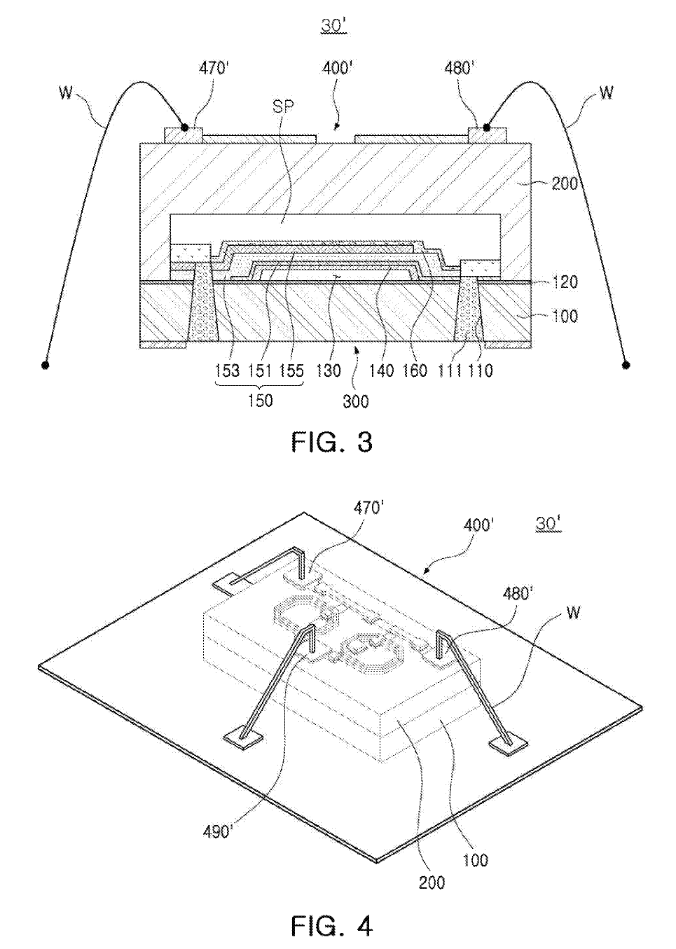

FIG. 3 is a cross-sectional view illustrating a filter module 30′, according to another embodiment. FIG. 4 is a perspective view illustrating the filter module 30′.

Referring to FIGS. 3 and 4, the filter module 30′ is the same as the filter module 30 in the embodiment of FIGS. 1 and 2, except for a disposition form of a second filter 400′, and a description for configurations other than the disposition form of the second filter 400′ will therefore be omitted.

In the filter module 30 according to the embodiment of FIGS. 1 and 2, the second filter 400 is disposed in the internal space SP formed by the first substrate 100 and the second substrate 200. However, in the filter module 30′ of FIGS. 3 and 4, the second filter 400′ is formed on an external surface of the second substrate 200.

As an example, the second filter 400′ is formed on a second surface of the second substrate 200 opposing a first surface of the second substrate 200 forming the internal space SP together with the first substrate 100.

The second filter 400′ is formed on the external surface of the second substrate 200, and input and output ports 470′ and 480′ and a ground 490′ of the second filter 400′ are electrically connected to the external substrate through wires W.

Therefore, the second filter 400′ can perform a filter operation of a radio frequency signal.

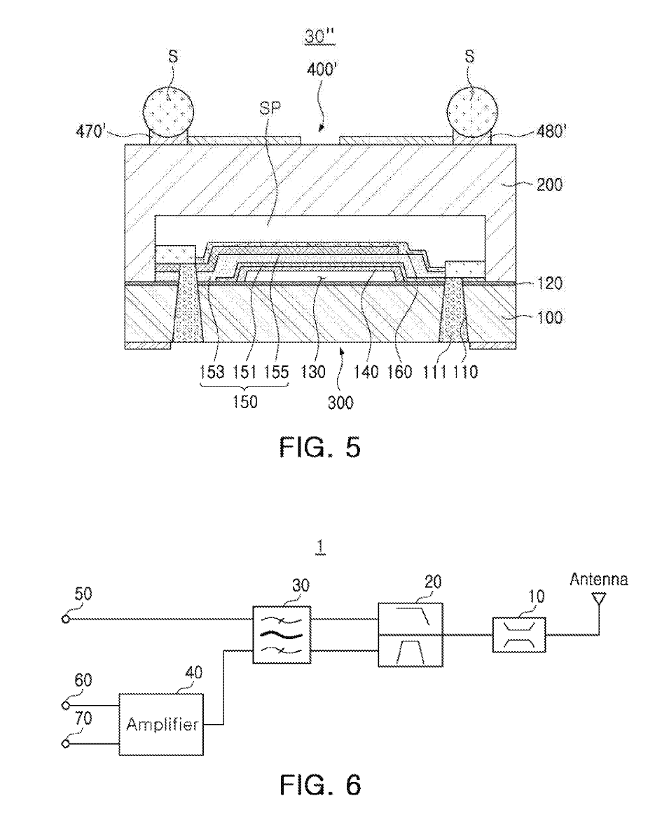

FIG. 5 is a cross-sectional view illustrating a filter module 30″, according to another embodiment.

Referring to FIG. 5, the filter module 30″ is the same as the filter module 30 in the embodiment of FIGS. 1 and 2, except for a disposition form of a second filter 400′, and a description for configurations other than the disposition form of the second filter 400′ will therefore be omitted.

In the filter module 30″ of FIG. 5, the second filter 400′ is formed on an external surface of the second substrate 200, like the filter module 30′ according to the embodiment of FIGS. 3 and 4.

However, unlike the filter module 30′ according to the embodiment of FIGS. 3 and 4, input and output ports 470′ and 480′ and a ground of the second filter 400′ are electrically connected to the external substrate through solder balls S.

Therefore, the second filter 400′ performs a filter operation of a radio frequency signal.

FIG. 6 is a block diagram illustrating an example of a front end module 1 including a filter module 30, according to an embodiment.

The front end module 1 may be used in an electronic device performing wireless communications using various communications networks such as global system for mobile communications (GSM), general packet radio service (GPRS), enhanced data GSM environment (EDGE), universal mobile telecommunications system (UMTS), code division multiple access (CDMA), wideband code division multiple access (WCDMA), long term evolution (LTE), and wireless broadband Internet (Wibro), and networks extended and deformed from the networks described above. The wireless communications networks described above may perform wireless communications in a multi-band manner using various frequency bands.

Referring to FIG. 6, the front end module 1 includes an antenna (“Antenna”), a coupler 10, a diplexer 20, and the filter module 30.

The antenna transmits and receives radio frequency signals in frequency bands, and the coupler 10 detects a strength of the radio frequency signals.

In addition, the diplexer 20 isolates the radio frequency signals in the frequency bands for each of the frequency bands. The radio frequency signals isolated by the diplexer 20 are transferred to the filter module 30.

Although the filter module 30 is shown in the front end module 1, the front end module 1 may also include either one of the filter modules 30′ and 30″ according to the embodiments of FIGS. 3 to 4 and FIG. 5, respectively.

The filter module 30 independently receives and filters the isolated radio frequency signals from the diplexer 20. As an example, the filter module 30 filters a frequency in a 2 GHz band and a frequency in a 5 GHz band. For example, the first filter 300 (FIG. 1) filters the frequency in the 2 GHz band, and the second filter 400 (FIG. 1) filters the frequency in the 5 GHz band.

The radio frequency signal in the 2 GHz band filtered by the filter module 30 is provided to a first transmit/receive end 50, and the radio frequency signal in the 5 GHz band filtered by the filter module 30 is provided to a second transmit end 60 and a second receive end 70 through an amplifier 40.

That is, the front end module 1 is configured so that the frequencies in the different bands are filtered by the filter module 30, resulting in the miniaturization of the electronic device.

As set forth in the embodiments above, in the filter module and the front end module including the filter module, sizes of the filter module and the front end module including the filter module may be reduced to miniaturize the electronic device including the front end module.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A filter module comprising:
a first substrate and a second substrate coupled to each other to form an internal space;
a first filter formed on the first substrate, in the internal space, and comprising a bulk acoustic resonator; and
a second filter disposed on the second substrate,
wherein the first and second filters are configured to filter frequencies within different bands.

2. The filter module of claim 1, wherein the second filter comprises either one of an active filter and a passive filter.

3. The filter module of claim 1, wherein the second filter comprises any one of a diplexer (DPX), a low pass filter (LPF), a high pass filter (HPF), a band pass filter (BPF), and a coupler.

4. The filter module of claim 1, wherein the second filter is disposed in the internal space.

5. The filter module of claim 1, wherein the second filter is formed on an external surface of the second substrate.

6. The filter module of claim 1, wherein the first and second substrates comprise high resistivity silicon (HRS) substrates.

7. The filter module of claim 1, wherein
the first filter is configured to filter frequencies within a first band, among the frequencies within the different bands, and
the second filter is configured to filter frequencies within a second band, among the frequencies within the different bands.

8. The filter module of claim 7, wherein the frequencies within the first band comprise frequencies within a 2 GHz band, and the frequencies within the second band comprise frequencies within a 5 GHz band.

9. A front end module comprising:
an antenna configured to transmit and receive radio frequency signals in frequency bands;
a diplexer configured to isolate the radio frequency signals received through the antenna in each of the frequency bands; and
a filter module configured independently receive and filter the isolated radio frequency signals from the diplexer,
wherein the filter module comprises
a first filter comprising a bulk acoustic resonator, and
a second filter comprising either one of a passive filter and an active filter.

10. The front end module of claim 9, wherein
the filter module further comprises a first substrate and a second substrate coupled to each other to form an internal space,
the bulk acoustic resonator is disposed on the first substrate, in the internal space, and
the either one of the passive filter and the active filter is disposed on the second substrate.

11. The front end module of claim 10, wherein the either one of the passive filter and the active filter is disposed in the internal space, facing the bulk acoustic resonator.

12. The front end module of claim 10, wherein the either one of the passive filter and the active filter is disposed on an external surface of the second substrate.

13. The front end module of claim 9, wherein
the first filter is configured to receive and filter first radio frequency signals, among the isolated radio frequency signals, that are in a first frequency band, among the frequency bands, and
the second filter is configured to receive and filter second radio frequency signals, among the isolated radio frequency signals, that are in a second frequency band, among the frequency bands.

14. The front end module of claim 13, wherein the wherein the first frequency band comprises a 2 GHz frequency band, and the second frequency band comprises a 5 GHz frequency band.
